(19) United States
(12) Patent Application Publication
(10) Pub. No.: US 2012/0088038 A1
(43) Pub. Date: Apr. 12, 2012

(54) Method and Device for High-Rate Coating by Means of High-Pressure Evaporation

(76) Inventor: Werner Prusseit, Munich (DE)

(21) Appl. No.: 13/266,805

(22) PCT Filed: Apr. 27, 2010
(86) PCT No.: PCT/EP10/55633

§ 371 Date: Dec. 27, 2011

(30) Foreign Application Priority Data
Apr. 29, 2009 (DE) 10 2009 019 146.1

(51) Int. Cl. C23C 16/448; C23C 16/52

(52) U.S. Cl. 427/580; 118/726; 118/723 VE; 118/723 EB; 427/250; 427/586

(57) ABSTRACT

The invention relates to a vacuum coating method with very high deposition rates at high layer thickness homogeneity and material yield as well as apparatuses for achieving the coating.

In order to overcome the existing conflict between layer thickness homogeneity on the one side and material yield and coating rate on the other side reducing the classic vacuum evaporation, the substrate forms the boundary of an essentially closed coating chamber which is supplied by an evaporation source. The walls of this coating chamber as well as all surfaces which are not to be coated are either kept at a certain temperature or provided with a non-stick coating such that the vapor cannot condensate thereon and is scattered back into the coating chamber. Thereby, a very high vapor pressure is created in the coating chamber which leads to a very high condensation rate onto the substrate and to a homogenization of the layer thickness. Since the substrate is the only surface on which the vapor may condensate, the amount of material that is lost is very low and the yield is extremely high. Through the use of a pulsed operation of the evaporation source, a short cycle coating can be realized.

### 1. TECHNICAL FIELD AND PROBLEM

The invention comprises a method for continuous or pulsed high rate coating of substrates and describes exemplarily apparatuses suited for realizing this method. The method is a type of vacuum coating that allows for very high deposition rates by allowing for a high homogeneity of layer thickness and material yield.

Many coating materials have a high chemical reactivity that let them react with constituents of the atmosphere such as oxygen and water so that they may only be deposited under suitable high vacuum conditions in order to avoid at least partial oxidation. These materials comprise generally the elements of the first three main groups of the periodic table of which aluminum and magnesium have a particularly high technical relevance but also many transition metals of the subgroups or noble earths have a very high chemical affinity to oxygen and a very high reduction potential when they are in atomic form. Beyond the simple elements, there is moreover a huge number of inorganic and organic chemical compounds that react chemically under contact with oxygen, water vapor or other oxygen comprising agents and may be changed.

Based on this high reactivity, many known high rate coating methods such as spray pyrolysis, chemical vapor phase deposition (CVD) or sole gel processes for coating are excluded. Sputtering techniques (cathode sputtering) are at least for many metals available; however they use a highly reactive process gas plasma wherein even traces of oxygen react with the coating material. For this reason, sputtering may only be performed using a low residual gas pressure (<10⁻⁵ Pa) and very clean process gases must be used. Moreover, due to the plasma, there is a high heat deposit into the substrate directly before the surface that is to be coated which is in many cases not wanted. The extremely high rate domain >100 nm/s is even for metals not accessible using sputtering.

A brilliant alternative is therefore in many cases the high rate evaporation in high-vacuum. Thereby, the coating material is heated by application of energy such that it transits into the vapor phase. According to prior art, this heating could for instance be achieved by thermal contact with a heated pot, direct electrical current flow, radiation, induction or an beam of electrons or an arc. The vapor ballistically disperses in the high-vacuum (<10⁻³ Pa) since there are only few collisions with the residual gas due to the large free path.

By using vacuum evaporation, very high deposition rates at the substrate may be achieved and even large areas may be coated homogeneously if the distance to the source is appropriate. Under ballistic propagation of the vapor the effective coating rate R on the substrate is inversely proportional to the square of the distance d to the source, i.e., R˜d⁻². The rate distribution and the layer thickness distribution on the substrate therefore follows only geometrical regularities and is usually described by a cosⁿφ-law. For low rates and in case of a plane substrate- and source surface n=4. Under high rate, one is already under the influence of the Knudsen flow and therefore a jet effect occurs due to the velocity distribution directed into the upper half space and due to collisions of the vapor molecules among themselves, wherein the jet effect additionally focuses the vapor distribution such that n>4 can be observed.

The usable angular area is defined by the angular distribution and the requirement for homogeneity of the layer thickness within a tolerable deviation. Therefrom follows, together with the size of the substrate, the lowest distance that has to be maintained between source and substrate. Any material which is not evaporated into the acceptable angular area is lost, reduces the yield and poses an unwanted contamination. The requirement for homogeneity therefore contradicts the requirement for high deposition rates and material yield. The invention overcomes this conflict by scattering the evaporated coating material that is initially not directed to the surface of the substrate back into the coating area and therefore the loss ratio can be kept low. The space in front of the substrate is such that there can be a high vapor pressure created such that the mean free path is clearly smaller than the geometrical dimensions of the coating chamber and the intense scattering results in a homogenization of the direction distribution in the vapor. For the high rate coating, typically vapor pressures >10 Pa and therefore mean free path lengths in the order of millimeters are desired. This can be achieved at least for short periods by pulsed evaporation of a specific amount of material.

The patent application publication DE 1 621 271 relates to a method for surface metal coating of a body using condensation of a metal that has been evaporated in vacuum. In particular, the invention relates to a method for creating vapor of a coating metal, wherein the vapor is free of particles which are comprised in the coating metal.

The U.S. Pat. No. 4,022,928 discloses coating of a surface with a perfluoropolyether-compound. Thereby, deposition of a vapor stream of material onto surfaces within a vacuum is inhibited. The perfluoropolyether protection layer can be applied by evaporation, spraying or spinning in vacuum or under atmospherical conditions or can be applied using a fluid or a thixotropic paste for instance by using a printing process.

In the publication “High Rate Vapor Deposition and Large System for Coating Processes” by S. Schiller, G. Beister, U. Heisig and H. Förster in J. Vac. Sci. Technol. A5(4), July/August 1987, p. 2239-2245, investigations regarding high rate electron beam evaporating and high rate sputtering are presented.

The EP 0 795 890 A2 discloses an apparatus for sputtering for reactive coatings of substrates wherein the electrical power that is applied to the sputtering electrode varies between two values. Both power values are chosen such that under constant flow of reactive gas, the target of the sputtering electrode is in the metallic mode for the first power value, while it is in the oxidic mode for the second power value.

The DE 101 53 760 A1 relates to a method for creating UV-absorbing transparent abrasion layers using vacuum coating, wherein simultaneously or directly successively at least one inorganic compound which creates layers with high abrasion resistance and one inorganic compound which creates layers with high UV-absorption are deposited on a substrate wherein the deposition is achieved in each case by reactive or partially reactive plasma-based high rate evaporation on a substrate.

### 2. DESCRIPTION OF THE INVENTION

In conventional high vacuum evaporation, the range of the molecular flow below 10⁻² Pa is used, i.e., the mean free path f of the vapor molecules is large or comparable to the geometric dimension L of the reservoir or the vacuum chamber, respectively. In this range, the vapor spreads ballistically and the vapor distribution is only according to geometrical regularities. In the pressure range above, which extends to approximately 1 Pa, the Knudsen flow follows wherein the mean free path f reaches from 0.01 L to 0.1 L. This is the transition range wherein scattering processes already influence the dynamic of the vapor. In the range of high rate coating with condensation rates above 10-100 nm/s one leaves the range of classical physical coating and reaches the range of flow above 1 Pa, wherein the vapor behaves like a streaming fluid and can be described using macroscopic physical status variables. The classification thereby follows “Woods Handbuch Vakuumtechnik”, Karl Josten (ed.) 9th revised edition ISBN-103-8348-0133-X.

The fundamental technical problem of high rate coating therefore is to provide a viscous flow within a high vacuum environment.

According to the invention, this problem is solved in that the coating occurs in a kind of pressure chamber in the high vacuum chamber. The volume within this pressure chamber defines the coating space.

The apparatus for high rate coating in high vacuum comprises an essentially closed coating space which is supplied with the vapor of a coating material by at least one evaporation source. The coating space is at least on one side limited by the substrate which is to be coated. In order to create a vapor pressure in the coating space which is as high as possible, preferably >10 Pa, the loss of material out of this space has to be kept as low as possible. The term “essentially dosed” therefore means in this context that the total cross section of all openings of the coating space through which vapor could escape is less than 10% of the coating surface of the substrate. Further, all surfaces which are not to be coated should be provided such that the vapor cannot condense on them but be scattered back into the coating space.

This assembly is schematically shown in FIG. 1. Within the coating chamber or surface-mounted thereon, there is a vapor generator which transitions the coating material from solid or liquid state into vapor state. Options for evaporation are known from the prior art, for instance heating by radiation, current, arc, electron beam or alternating electromagnetic fields. The walls of the coating chamber and all mounts that scatter back the vapor and on which the condensation of the vapor should be avoided are either provided with a non-stick coating or have an appropriate temperature. In the latter, the surface is maintained on a temperature such that the vapor pressure of the coating material is larger than that of the coating chamber. This seems only feasible if the coating material has a high vapor pressure already at low temperature. The heated walls form a hot half space before the substrate due to the closed assembly wherein the radiation of the hot half space presents an additional heating contribution to the substrate. Therefore, it has to be determined for each case whether this heating contribution is acceptable or whether it has to be dissipated using an active cooling of the substrate.

The more convenient and better solution of this problem is a non-stick coating that avoids the condensation and the adherence of the coating material, respectively, even at low temperatures. Such non-stick coatings are known, e.g., by the U.S. Pat. No. 4,022,928. Therein, long-chained perfluoropolyether (PFPE) avoid the condensation of various metals on the treated surfaces. In order to avoid a contamination of the coating by the non-stick material, it is recommended to use a non-stick coating made of perfluoropolyether which has a vapor pressure of less than 10⁻⁵ Pa at room temperature. Preferably, the vapor pressure should be less than 10⁻⁸ Pa. Since the vapor pressure increases with temperature, in one preferred embodiment all surfaces coated with the non-stick material are actively cooled.

In this arrangement, the coating material essentially condenses only on the surface of the substrate as desired without contamination of the walls and the surface is the only material sink in the coating chamber. Thereby, a very high material yield and low contamination of surrounding parts can be assured. The loss of material corresponds to the area ratio of parasitic coated parts and openings to the surface of the substrate.

The dynamic vapor pressure gradient in the coating chamber can be calculated classicaly as for each gas flow through material inflow (source) and outflow (condensation on the substrate). The upper limit of the pressure in the coating chamber is given by the vapor pressure at source temperature. This can be in the range of 10-100 Pa without any problems. The rate of condensation on the substrate naturally depends also on its temperature. Typically, the substrate is considerably cooler than the source of the evaporator. Since the rate of condensation increases exponentially with the temperature difference, the substrate represents a very effective material sink and basically soaks the material like a sponge out of the coating chamber. Thereby it is possible to reach very high condensation rates >10 nm/s and the extremely high rates >100 nm/s and extremely short processing times in the range of few seconds, respectively, can be achieved.

In this process management, the coated substrates have to be replaced with new ones at short clock cycles. Since the substrate closes the coating chamber, during the replacement vaporous coating material is lost when the chamber is used in continuous operation. If the duration of replacement is short (<10%) compared to the coating period, the loss may be acceptable. If short cycle operation is desired, it is recommended to operate the evaporation source in pulsed mode. By the pulsed release of vapor, it is possible to maintain a vapor pressure level >10 Pa at least for a short time period. This pressure level is several orders of magnitude above that of the surrounding vacuum and allows for extremely high rates of vapor condensation >100 nm/s on the substrate.

Within few seconds, preferably within less than 10 seconds, the full amount of material which is required for the coating is evaporated. In order to keep the time constants which are given by the thermic inactivity of the evaporator as low as possible, preferably only the required coating material is heated. To this end, arc discharges, electromagnetic high frequency or laser pulses or a modulated electron beam are particularly suitable. In this case, the coating material has to be continuously adjusted. If the material source consists of a continuously operation effusion cell, it is possible to open and dose this effusion cell periodically using a cover in order to realize a clocked operation. However, in this case also similar measures (heating, non-stick cover) as for the chamber walls have to be made in order to avoid a coating of the cover.

Even though the method represents a real high-vacuum coating—since the residual gas pressure in the system is less than 10⁻³ Pa—the coating chamber is filled with a relatively dense vapor cloud during the coating phase. Due to the frequent collisions of the vapor molecules among each other and with the walls, the original direction information at the emission from the source gets very quickly lost which leads to a rather isotropic direction distribution within the vapor. The variations of layer thickness over the surface of the substrate are correspondingly lower.

However, it is possible to foresee screens or blinds within the coating chamber in order to direct the vapor and/or to protect the substrate and/or to homogenize the layer thickness on the substrate. For instance, it is possible to avoid material reaching the substrate on a direct line of sight from the source by using a screen (cf. FIG. 2). Should during the fast evaporization splashes or larger particles escape, this screen could also avoid an unwanted contamination of the substrate by these particles or be used to shield the thermal radiation from the evaporation source. Of course for all of these screens or blinds, the same provisions have to be made as for all other surfaces which shall not be coated. Either they have to be maintained at sufficiently high temperature or they have to be fully covered with a non-stick coating and be actively cooled.

### 3. SHORT DESCRIPTION OF THE FIGURES

In the following, preferred embodiments of the invention are explained in the context of the following accompanying figures:

FIG. 1: schematical drawing of the device for high pressure evaporation

FIG. 2: high pressure evaporator with blind for blinding the direct line of sight from the source to the substrate

FIG. 3: high pressure evaporator with mounted-on effusion cell

FIG. 4: arc evaporator with electrode material feed as source in the high pressure evaporator

FIG. 5: high pressure evaporating device with laser or electron beam heated source with material feed

### NOMENCLATURE

1 coating chamber
2 chamber wall
3 evaporation source
4 substrate
5 cooling or heating elements
6 blind, screen
7 effusion cell
8 cover of effusion cell
9 arc
10 traceable metal electrodes
11 traceable evaporation material
12 laser or electron beam

### 4. DETAILED DESCRIPTION OF THE FIGURES AND PREFERRED EMBODIMENTS

In the following, several preferred embodiments of the high pressure evaporator are described in more detail.

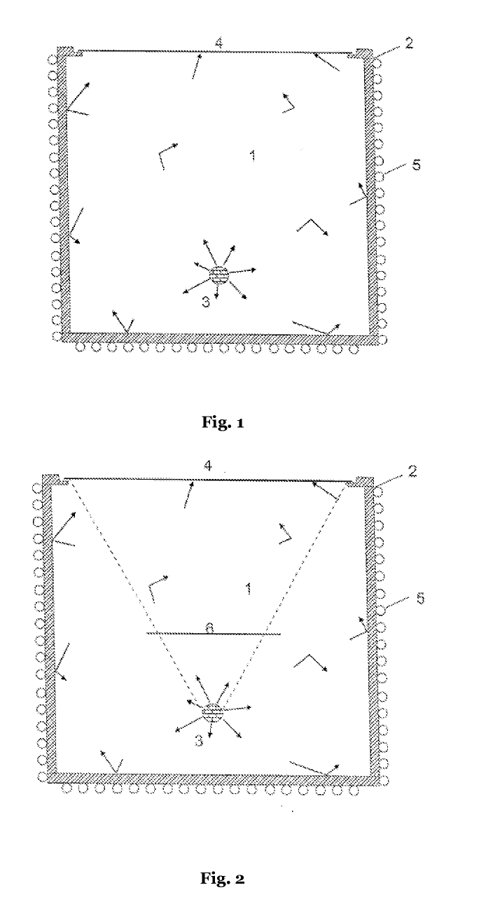

FIG. 1 shows a schematical drawing of the high pressure evaporator. The coating chamber 1 is confined by walls 2 and at least on one side by the substrate 4 that is to be coated. This arrangement can itself be located inside of a high vacuum chamber that can be set to an appropriate background pressure <10⁻³ Pa by using appropriate pumps so that before the coating begins, only traces of oxygen or water vapor are present within the chamber. Within the coating chamber or connected to it, there is at least one evaporation source 3 which transitions the coating material into the vapor phase. All surfaces that are not to be coated must have a very low vapor adhesion coefficient.

For coating materials that develop a high vapor pressure already at moderate temperatures, the condensation can be avoided by adjusting the temperature of these surfaces such that the vapor pressure at these surfaces is larger than within the coating chamber.

In one practical example, magnesium shall be deposited as metal on a semiconductor substrate as electrical conductive contacting layer. To this end, the walls of the coating chamber 2 are kept at a temperature above 550° C. using heating elements 5, while the temperature of the substrate during the process does not exceed 250° C. Thereby, the magnesium vapor deposits nearly completely on the surface of the substrate. The walls are not coated. A very similar procedure is possible, e.g., for many organic substances as long as they do not decay on the heated walls (pyrolysis).

However, most of the technically interesting metals, such as aluminum, chromium, copper or noble metals have a vapor pressure >10 Pa only at temperatures above 1000° C. In such cases, heating of the walls is not feasible. It is therefore recommended to reduce the adhesion coefficient using a non-stick coating. Suitable coatings preferably are made of long chained PFPE-compounds (e.g., Fomblin). In order to keep the vapor pressure of the PFPE-compound low and to dissipate the heat radiation from the evaporating source, the coated parts connected therewith are preferably actively cooled. For adjusting the temperature of the wall 5, e.g., cooling elements such as water conduits can be used as cooling elements. In this case, the wall material 2 should be made of a material which is a good heat conductor. Preferred are materials with a thermal conduction coefficient of λ>80 W/(m*K) such as aluminum, copper and alloys of these metals.

In order to homogenize the distribution of layer thickness on the substrate it may be advisable to mount blinds or screens 6 in the coating chamber. This is exemplarily shown in FIG. 2 wherein a screen masks the direct line of sight from the source to the substrate. Thus, the coating material can only reach the substrate on an indirect path through scattering. Such a blind can also avoid the contamination of the substrate or a heating contribution by the source. Blinds can be made in arbitrary geometric forms, e.g. as perforated metal plate. As they are not to be coated they are, depending on the process management, supplied with a heating or with a non-stick coating and a cooling (not shown), just like the chamber wall.

Openings of the coating chamber are competing with the substrate for the coating material which reduces the yield. Therefore, the evaporation sources are preferably located within the coating chamber or directly mounted thereon. In order to assure long time operation, these evaporators must either have a large material volume or must be charged from the outside. In the following, several preferred embodiments are described as examples.

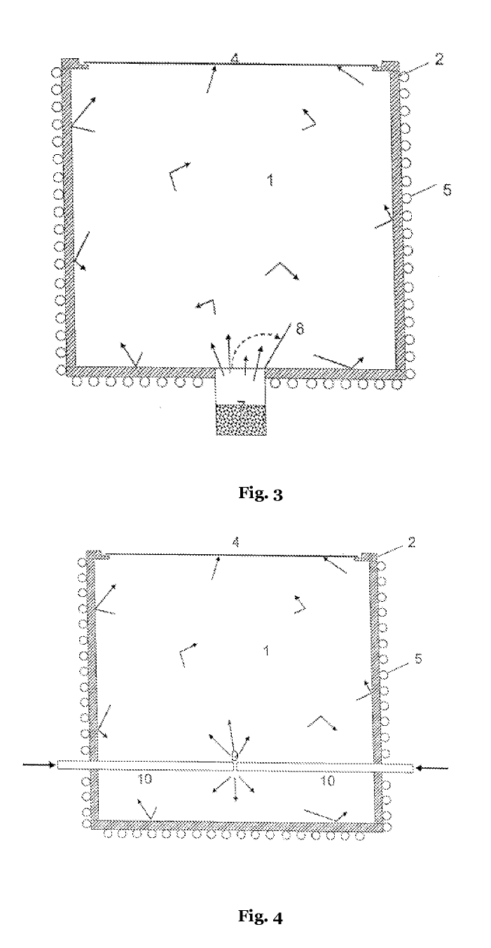

FIG. 3 shows a customary heated effusion cell with limited material volume 7 which is directly mounted on the coating chamber. It is maintained at high temperature and releases the material with high vapor pressure. In order to realize a pulsed operation, the hot effusion cell 7 may be opened and closed with a cover 8. To avoid coating of the cover, it has either to be kept at high temperature like the chamber walls or screens or it has to be provided with a non-stick coating.

To vaporize metals within the coating chamber it is also possible to use an arc evaporator 9 whose electrodes can be adjusted. This is for example shown in FIG. 4. The coating material is inserted into the coating chamber in the form of two wires or sticks 10 through sockets in the wall of the chamber wherein they are located next to each other except for a small slot. By applying a high voltage or a high voltage pulse, respectively, a sparkover is created on whose end points electrode material evaporates and thereby creates a conducting gas channel. This allows for a high current flow between the electrodes, and the arc allows for a smooth vaporization of the electrode material. The electrodes 10 are traced until the desired amount of material is evaporated and the arc is turned off, e.g., by disconnecting the current flow or by increasing the distance between the electrodes. In this arrangement, there are no further components of the source within the coating chamber besides the coating material in form of the electrodes. The material is heated selectively at the tip of the electrodes and very efficiently evaporated.

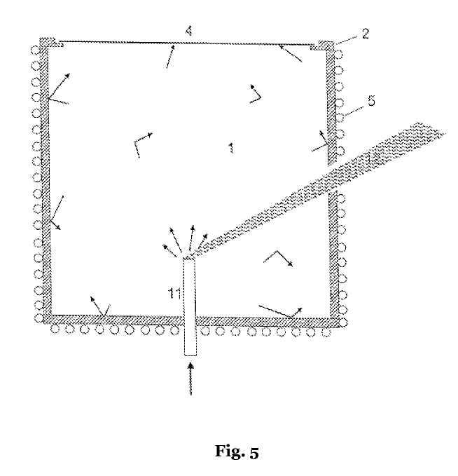

A further exemplary arrangement is shown in FIG. 5. In this case, the coating material 11 is applied through a socket in the wall of the coating chamber. For heating and evaporating of the refillable material supply, a power regulated high energy laser or electron beam 12 is used, which is created outside of the coating chamber and directed onto the coating material through an opening in the chamber wall which is as small as possible. Also in this arrangement, a pulsed mode is possible by modulating the power of the beam.

### Further Embodiments of the Present Invention

1. An apparatus for high rate coating in high-vacuum, comprising an essentially closed coating chamber which is supplied with vapor of a coating material using at least one evaporation source, characterized in that:
   a. the coating chamber is confined on at least one side by the substrate,
   b. the total cross section of all openings of the coating chamber corresponds to less than 10% of the coating surface of the substrate,
   c. all surfaces that are not to be coated are provided such that vapor cannot condense on them, and
   d. the effective rate of condensation onto the substrate is >10 nm/s.
2. The apparatus according to example 1, characterized in that all surfaces on which condensation of vapor is to be avoided are either kept at an appropriate temperature or provided with a non-stick coating.
3. The apparatus according to one of the examples 1 or 2, characterized in that the non-stick coating consists of a perfluoropolyether which has a vapor pressure of less than 10⁻⁵ Pa at room temperature.
4. The apparatus according to one of the examples 1 to 3, characterized in that the surfaces which are provided with the non-stick coating are actively cooled.
5. The apparatus according to one of the examples 1 to 4, characterized in that the vapor pressure in the coating chamber reaches at is least 10 Pa during the coating phase.
6. The apparatus according to one of the examples 1 to 5, characterized in that within the coating chamber blinds or screens are provided for directing the metal vapor and/or for protecting the substrate and/or for homogenizing the layer thickness on the substrate.
7. The apparatus according to one of the examples 1 to 6, characterized in that the evaporation source is operated in pulsed mode such that within few seconds, preferably in less than 10 seconds, the amount of material necessary for the coating is evaporated, such that a short cycle operation is possible.
8. The apparatus according to one of the examples 1 to 7, characterized in that the evaporation source consists of a hot effusion cell which can be opened and closed using a cover.
9. The apparatus according to one of the examples 1 to 7, characterized in that the evaporation source consists of an arc evaporator which has electrodes that can be traced.
10. The apparatus according to one of the examples 1 to 7, characterized in that the evaporation source comprises a refillable material supply which is evaporated using a power controlled laser or electron beam.
11. A method for high rate coating of metals in high-vacuum, characterized in that:
   a. the coating takes place within an essentially dosed coating chamber which is supplied by at least one evaporation source and
   b. that the coating chamber is confined on at least one side by the substrate,
   c. and the vaporous coating material is scattered back by the walls of the coating chamber,
   d. such that a vapor pressure >10 Pa is created in the coating chamber, and
   e. the vapor of the material condenses essentially on the substrate without contaminating the walls.

1.-9. (canceled)

10. An apparatus for high rate coating of metals in high-vacuum, comprising:
a coating chamber within the high-vacuum comprising at least one opening to the high-vacuum; and
at least one evaporation source which is arranged such that it emits metal vapor particles into the coating chamber;
wherein the coating chamber is confined on at least one side by a substrate;
wherein all surfaces which are not to be coated are provided with a non-stick coating; and
wherein openings of the coating chamber to the high-vacuum are configured to have a total cross section such that after switching on the evaporation source, starting from a high vacuum constraint a metal vapor pressure in the coating chamber reaches at least 10 Pa during the coating phase, and wherein a viscous flow of the metal vapor particles from the evaporation source to the substrate is created in the coating chamber.

11. The apparatus of claim 10, wherein the non-stick coating comprises a perfluoropolyether which has a vapor pressure of less than 10⁻⁵ Pa at room temperature.

12. The apparatus of claim 10, wherein the surfaces provided with the non-stick coating are actively cooled.

13. The apparatus of claim 10, wherein within the coating chamber blinds or screens are provided for directing the metal vapor and/or for protecting the substrate and/or for homogenizing the layer thickness on the substrate.

14. The apparatus of claim 10, wherein the evaporation source is operated in pulsed mode such that within less than 10 seconds, the amount of material necessary for the coating is evaporated, such that a short cycle operation is possible.

15. The apparatus of claim 10, wherein the evaporation source comprises a hot effusion cell which can be opened and closed using a cover.

16. The apparatus of claim 10, wherein the evaporation source comprises an arc evaporator which has electrodes that can be traced.

17. The apparatus of claim 10, wherein the evaporation source comprises a refillable material supply which is evaporated using a power controlled laser or electron beam.

18. The apparatus of claim 10, wherein the total cross section of all openings of the coating chamber corresponds to less than 10% of the coating surface of the substrate.

19. The apparatus of claim 10, wherein the effective rate of condensation onto the substrate is greater than 10 nm/s.

20. A method for high rate coating of metals in high-vacuum, comprising:
providing a coating chamber within the high-vacuum comprising at least one opening to the high-vacuum;
providing at least one evaporation source which is arranged such that it emits metal vapor particles into the coating chamber;
wherein the coating chamber is confined on at least one side by a substrate;
wherein all surfaces which are not to be coated are provided with a non-stick coating; and
wherein openings of the coating chamber to the high-vacuum are configured to provide a total cross section such that after switching on the evaporation source, starting from a high vacuum constraint a metal vapor pressure in the coating chamber reaches at least 10 Pa during the coating phase, and wherein a viscous flow of the metal vapor particles from the evaporation source to the substrate is created in the coating chamber; and
coating at least a part of the substrate in the coating chamber using the at least one evaporation source.

21. The method of claim 20, wherein the non-stick coating consists of a perfluoropolyether which has a vapor pressure of less than 10⁻⁵ Pa at room temperature.

22. The method of claim 20, wherein the surfaces provided with the non-stick coating are actively cooled.

23. The method of claim 20, wherein within the coating chamber blinds or screens are provided for directing the metal vapor and/or for protecting the substrate and/or for homogenizing the layer thickness on the substrate.

24. The method of claim 20, wherein the evaporation source is operated in pulsed mode such that within less than 10 seconds, the amount of material necessary for the coating is evaporated, such that a short cycle operation is possible.

25. The method of claim 20, wherein the evaporation source comprises a hot effusion cell which can be opened and closed using a cover.

26. The method of claim 20, wherein the evaporation source comprises an arc evaporator which has electrodes that can be traced.

27. The method of claim 20, wherein the evaporation source comprises a refillable material supply which is evaporated using a power controlled laser or electron beam.

28. The method of claim 20, wherein the total cross section of all openings of the coating chamber corresponds to less than 10% of the coating surface of the substrate.

29. The method of claim 20, wherein the effective rate of condensation onto the substrate is greater than 10 nm/s.
